(19) United States
(12) Patent Application Publication
(10) Pub. No.: US 2026/0371519 A1
(43) Pub. Date: Nov. 19, 2026

(54) LIQUID COOLING HEAT SINK AND MANUFACTURING METHOD THEREOF

(71) Applicant: NIDEC CHAUN-CHOUNG TECHNOLOGY CORPORATION, NEW TAIPEI CITY (TW)

(72) Inventors: Sung-Wei LEE, NEW TAIPEI CITY (TW); Po-Han LIN, NEW TAIPEI CITY (TW); Tun-Hao HU, NEW TAIPEI CITY (TW); Chang-Yen LEE, NEW TAIPEI CITY (TW); Jeff Carlo MANINANG, NEW TAIPEI CITY (TW)

(21) Appl. No.: 19/222,757

(22) Filed: May 29, 2025

(30) Foreign Application Priority Data
Mar. 20, 2025 (TW) 114110498

(51) Int. Cl. H05K 7/20; B23P 15/26

(52) U.S. Cl. CPC H05K 7/20218; B23P 15/26

(57) ABSTRACT

A liquid cooling heat sink includes a base and a top plate, the base includes parallel cooling fins, a notch formed by at least a part of cooling fin, the top plate combines the base, covers each cooling fin, and includes a liquid inlet, a liquid outlet, a separation plate and a protruding rib, the separation plate is parallel to each cooling fin and divides each cooling fin into a liquid inlet fin module corresponding to the liquid inlet fin module and a liquid outlet fin module corresponding to the liquid outlet fin module, the protruding rib is accommodated in a ditch and abuts against each corresponding cooling fin, and the protruding rib is perpendicular to each cooling fin and the separation plate; the coolant passing through the liquid inlet fin module to the bottom is blocked by the protruding rib to improve the heat dissipation efficiency.

### BACKGROUND OF THE DISCLOSURE

### Technical Field

The present disclosure relates to the technical field of liquid cooling heat dissipation, particularly relates to a liquid cooling heat sink and a manufacturing method thereof.

### Description of Related Art

With the booming development of electronic technology, various electronic devices and electronic equipment tend to be developed with a high-efficiency and thin design. As a result, a large amount of heat is generated during operation, making traditional air-cooling or cooling fins inadequate to meet the heat dissipation requirements. Therefore, liquid cooling heat sinks such as liquid cooling heads, liquid cooling plates or liquid cooling racks have gradually become a mainstream heat dissipation method. The liquid cooling heat sink is usually installed on a heat source such as a motherboard or processor and a coolant is infused into the liquid cooling heat sink and allowed to flow through a plurality of cooling fins to absorb the heat generated by the heat source, so as to achieve the cooling effect.

However, the related-art liquid cooling heat sink is limited by its volume and size, which causes the coolant to reside in the interior for a too-short period of time, results in the limited amount of heat energy to be absorbed by the coolant, and fails to effectively maximize the cooling efficiency of the liquid cooling heat sink. Therefore, how to increase the heat dissipation efficiency by improving the heat absorption and lengthening the residence time of the coolant under the condition of limited volume demands immediate attentions and feasible solutions.

In view of the deficiencies of the related art, the present discloser conducted researches based on the existing technologies and the application of theories, and finally developed the liquid cooling heat sink and the manufacturing method thereof in accordance with the present disclosure to overcome the deficiencies of the related art.

### SUMMARY OF THE DISCLOSURE

The primary objective of the present disclosure is to enhance the heat dissipation efficiency of a liquid cooling heat sink by allowing a coolant to flow to the bottom of a liquid inlet fin module when the coolant is blocked by a protruding rib to adjust the flow rate of the coolant and increase the amount of heat absorbed by the coolant.

To achieve the aforementioned objective, the present disclosure provides a liquid cooling heat sink, which includes a base and a top plate, wherein the base has a plurality of cooling fins configured to be parallel to each other and at least a part of each cooling fin being formed into a notch, and each notch being jointly formed into a ditch; and the top plate is correspondingly combined with the base and covers each cooling fin, and the top plate includes a liquid inlet, a liquid outlet, a separation plate and a protruding rib, and the separation plate is parallel to each cooling fin and divides each cooling fin into a liquid inlet fin module and a liquid outlet fin module, the liquid inlet is configured to correspond to the liquid inlet fin module, the liquid outlet is configured to correspond to the liquid outlet fin module, the protruding rib is accommodated in the ditch and abuts against each corresponding each cooling fin, and the protruding rib is perpendicular to each cooling fin and the separation plate.

In an embodiment of the present disclosure, each notch is formed on each cooling fin of the liquid inlet fin module.

In an embodiment of the present disclosure, the protruding rib extends from the top plate to abut against the liquid inlet fin module.

In an embodiment of the present disclosure, the ratio of the depth of the ditch to the height of the liquid inlet fin module from 0.1 to 1.

In an embodiment of the present disclosure, the ratio of the depth of the ditch to the height of the liquid inlet fin module is 0.5.

In an embodiment of the present disclosure, the protruding rib is located between the liquid inlet and the liquid outlet.

In an embodiment of the present disclosure, the liquid inlet and the liquid outlet are diagonally arranged on two opposite sides of the separation plate respectively.

In an embodiment of the present disclosure, the ratio of the volume of the liquid inlet fin module to the volume of the liquid outlet fin module is from 1 to 5.

In an embodiment of the present disclosure, the ratio of the volume of the liquid inlet fin module to the volume of the liquid outlet fin module is 2.

To achieve the aforementioned objective, the present disclosure also provides a manufacturing method of a liquid cooling heat sink, which includes a pre-processing step, a skiving step and a combining step. In the pre-processing step, a base plate is provided, and the upper surface of the base plate is formed with a trench. In the skiving step, the upper surface of the base plate is skived to form a liquid inlet fin module and a liquid outlet fin module, the trench is transformed into a ditch when the base plate is skived to form the liquid inlet fin module, and the ditch is located on a side of the liquid inlet fin module away from the upper surface of the base plate. In the combining step, a top plate is provided, the lower surface of the top plate is provided with a surrounding wall, a separation plate and a protruding rib, the separation plate and protruding rib are located in the surrounding wall, the protruding rib is perpendicular to the separation plate, the top plate is combined with the base plate, so that the surrounding wall surrounds the liquid inlet fin module and the liquid outlet fin module and blocks the separation plate between the liquid inlet fin module and the liquid outlet fin module, and the protruding rib is accommodated in the ditch and abuts against the liquid inlet fin module.

The liquid cooling heat sink of the present disclosure has a ditch formed in at least a part of a cooling fin, a top plate having a protruding rib corresponding to each cooling fin accommodated in the ditch and abutting against the corresponding fin, and a separation plate is used to separate each cooling fin into a liquid inlet fin module and a liquid outlet fin module corresponding to a liquid inlet and a liquid outlet, respectively. Therefore, when the coolant passes through the liquid inlet fin module, it is blocked by the protruding rib and flows to the bottom, thereby adjusting the flow rate of the coolant and increasing the heat absorption of the coolant, and improving the heat dissipation efficiency of the liquid cooling heat sink.

The present disclosure provides a manufacturing method of a liquid cooling heat sink, wherein a trench is first formed on the upper surface of a base plate through a pre-processing step, and then a high-density liquid inlet fin module and a high-density liquid outlet fin module are integrally formed on the upper surface of the base plate through a skiving step, so that the trench is transformed into a ditch located on the side of the liquid inlet fin module away from the upper surface of the base plate, and finally a top plate is combined with the base so that the protruding rib is accommodated in the ditch and abuts against the liquid inlet fin module, and the coolant is blocked by the protruding rib when passing through the liquid inlet fin module and flows to the bottom, thus adjusting the flow of the coolant, increasing the heat absorption of the coolant at the bottom, and improving the heat dissipation efficiency of the liquid cooling heat sink.

### BRIEF DESCRIPTION OF THE DRAWINGS

FIG. 1 is a perspective view showing the disassembled parts of a liquid cooling heat sink of the present disclosure.

FIG. 2 is a perspective view of a base of the liquid cooling heat sink of the present disclosure.

FIG. 3 is a perspective view showing the disassembled parts of the liquid cooling heat sink of the present disclosure during application.

FIG. 4 is a cross-sectional side view of the liquid cooling heat sink of the present disclosure during application.

FIG. 5 is another cross-sectional side view of the liquid cooling heat sink of the present disclosure during application.

FIG. 6 is a cross-sectional top view of the liquid cooling heat sink of the present disclosure during application.

FIG. 7 is another cross-sectional top view of the liquid cooling heat sink of the present disclosure during application.

FIG. 8 is a flow chart of a manufacturing method of a liquid cooling heat sink in accordance with the present disclosure.

### DETAILED DESCRIPTION

In the description of the present disclosure, it should be understood that the terms “front side”, “rear side”, “left side”, “right side”, “front end”, “rear end”, “end”, “longitudinal”, “lateral”, “vertical”, “top”, “bottom” and the like indicate positions or positional relationships based on the positions or positional relationships shown in the drawings, and they are only used to facilitate the description of the present disclosure and simplify the description, but do not indicate or imply that the device or element referred to must have a specific orientation, be constructed and operate in a specific orientation. Therefore, these terms should not be understood as a limitation to the present disclosure.

As used herein and not otherwise defined, the terms “substantially” and “approximately” are used to describe and narrate small variations. When combined with an event or situation, the term may include the exact moment when the event or situation occurs, and the event or situation occurs to a close approximate point. For example, when combined with a numerical value, the term may include a variation range of less than or equal to 10% or more than or equal to 10% of the numerical value, such as less than or equal to 5% or more than or equal to 5%, or less than or equal to 4% or more than or equal to 4%, less than or equal to 3% or more than or equal to 3%, or less than or equal to 2% or more than or equal to 2%, or less than or equal to 1% or more than or equal to 1%, or less than or equal to 0.5% or more than or equal to 1%, or less than or equal to 0.1% or more than or equal to %, or less than or equal to 0.05% or more than or equal to 0.05% of the numerical value.

The detailed description and technical contents of the present disclosure are illustrated with reference to the accompanying drawings, which are intended for the illustrative purposes only, but not intended for limiting the disclosure.

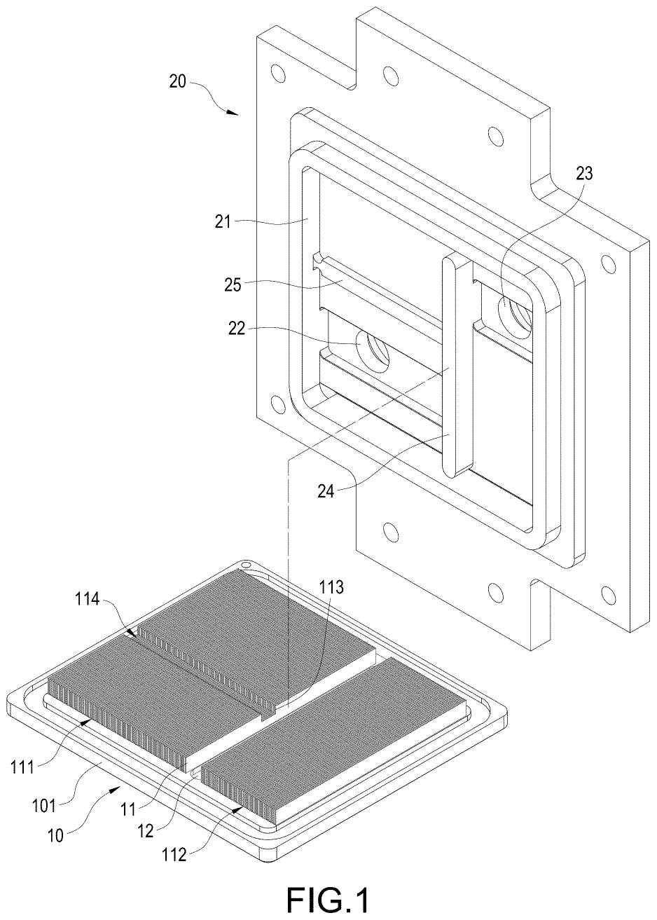

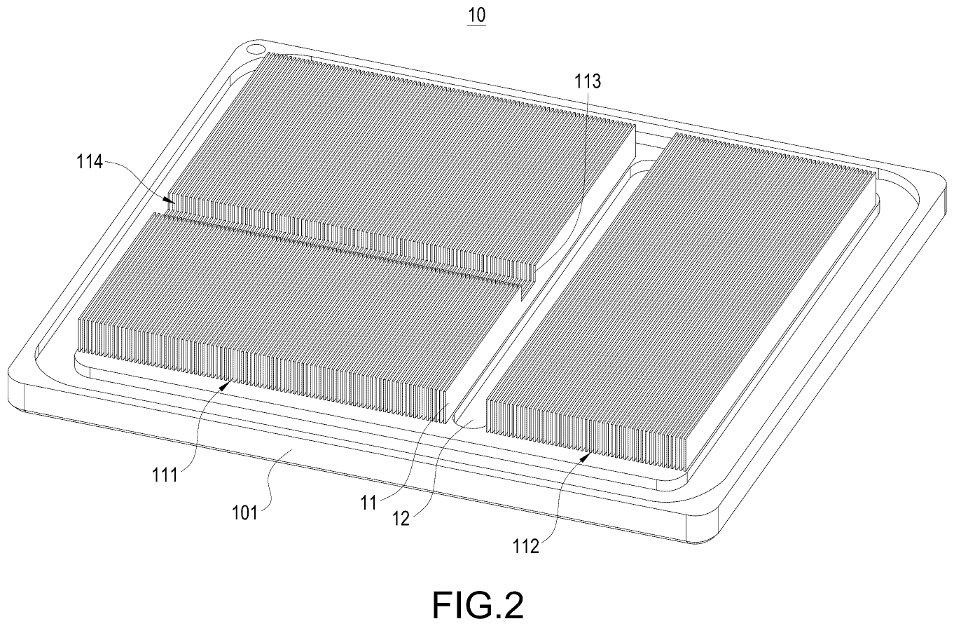

The present disclosure provides a liquid cooling heat sink, which is used to be attached to at least one heat source (not shown in the figures) and allows a coolant (not shown in the figures, only the flow direction is indicated by an arrow) to flow through, so as to dissipate heat from the heat source. Referring to FIGS. 1 and 2, the liquid cooling heat sink of the present disclosure includes a base 10 and a top plate 20.

In this embodiment, the base 10 is made of a metal with desirable thermal conductivity such as copper or aluminum, but the present disclosure does not particularly limit the specific material, as long as the base 10 is made of a material with desirable thermal conductivity. The base 10 of this embodiment is a rectangular base plate 101, but the shape of the base 10 can be adjusted according to different needs. The base 10 has a plurality of cooling fins 11 arranged in parallel, and a flow channel (not labeled in the figure) formed between two adjacent cooling fins 11. In some embodiments, each cooling fin 11 is integrally formed on the upper surface of the base plate 101 to form the base 10. In this embodiment, each cooling fin 11 consists of a plurality of skived fins directly integrally formed on the base 10 by skiving, so that a one-piece high-density cooling fin 11 is easily and directly formed on the base 10, thereby effectively improving the heat dissipation efficiency and preventing the fins from increasing thermal resistance due to welding. In addition, each cooling fin 11 is divided into two areas to form a liquid inlet fin module 111 and a liquid outlet fin module 112, and a positioning groove 12 is formed between the liquid inlet fin module 111 and the liquid outlet fin module 112.

At least a part of each cooling fin 11 is formed with a notch 113. In this embodiment, each notch 113 is formed on each cooling fin 11 of the liquid inlet fin module 111 and jointly forms a ditch 114, but the present disclosure is not limited thereto. For example, each notch 113 of some embodiments is formed on each cooling fin 11 of the liquid outlet fin module 112, or formed on each cooling fin 11 of the liquid inlet fin module 111 and the liquid outlet fin module 112 at the same time. In an embodiment, each notch 113 is formed on a side of the cooling fin 11 away from the base 10, that is, each notch 113 is formed on the top of the cooling fin 11. In particular, the base 10 of this embodiment first forms a trench on the upper surface of a base plate, and then integrally forms a high-density liquid inlet fin module 111 and a high-density liquid outlet fin module 112 on the upper surface of the base plate by skiving, so that the trench is transformed into a ditch 114 located on the side of the liquid inlet fin module 111 away from the upper surface of the base plate, thereby achieving the effects of forming the ditch 114 on the high-density skived fin without destroying the skived fin structure, simplifying the processing method and lowering the cost.

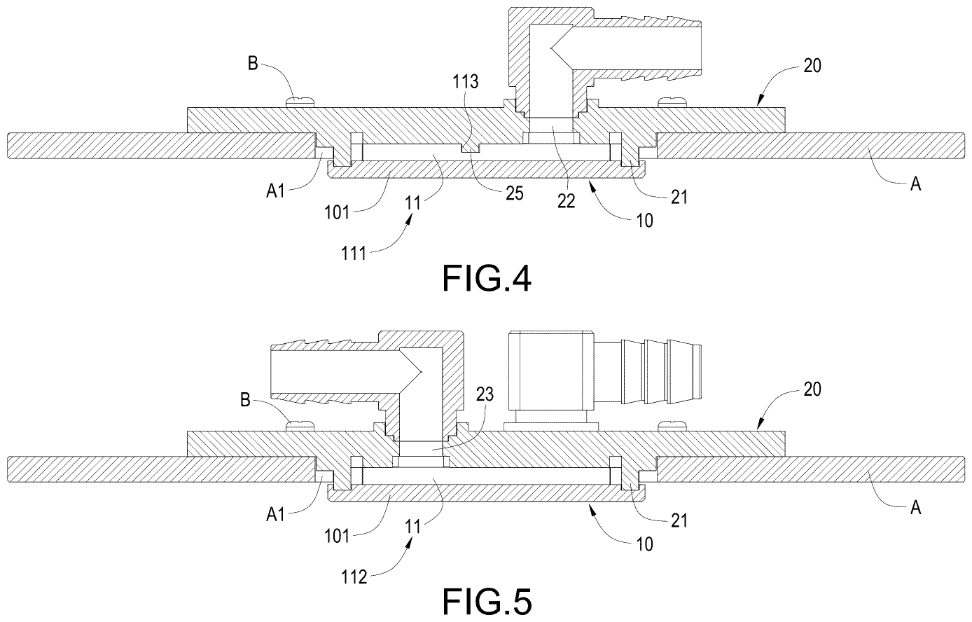

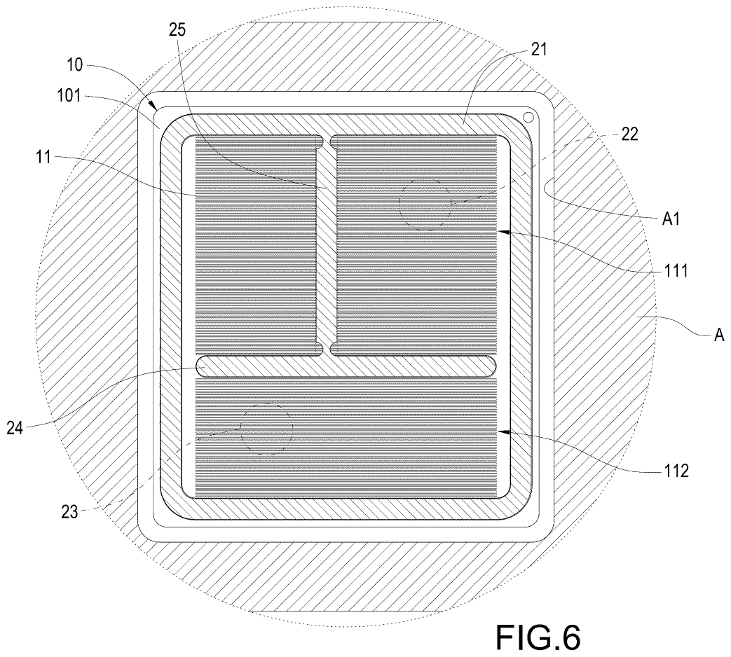

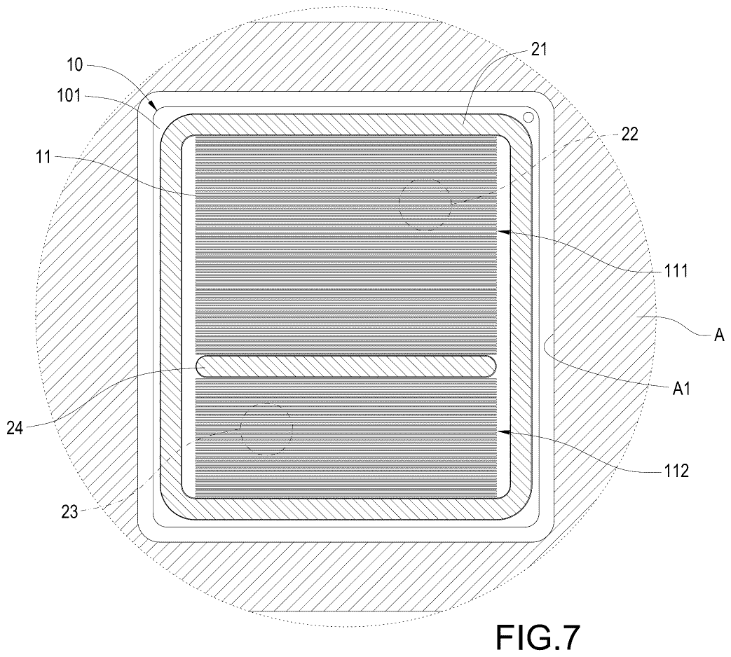

In this embodiment, the top plate 20 is made of a metal with desirable thermal conductivity, such as copper or aluminum, but the present disclosure does not particularly limit the specific material, as long as the top plate 20 is a material with desirable thermal conductivity. With reference to FIGS. 4 and 5, the top plate 20 combines with the base 10 and covers and abuts against the top of each cooling fin 11. In this embodiment, the top plate 20 is fixed to the base 10 by welding, but the present disclosure is not limited thereto. The top plate 20 includes a surrounding wall 21, a liquid inlet 22, a liquid outlet 23, a separation plate 24 and at least one protruding rib 25. The liquid inlet 22, the liquid outlet 23, the separation plate 24 and the protruding rib 25 are all located in the surrounding wall 21, and the surrounding wall 21 surrounds each cooling fin 11 of the base 10 and abuts against the base 10. With reference to FIGS. 6 and 7, the separation plate 24 is parallel to each cooling fin 11, and abuts against the positioning groove 12 of the base 10 to divide each cooling fin 11 into a liquid inlet fin module 111 and a liquid outlet fin module 112. The liquid inlet 22 and the liquid outlet 23 are arranged on two opposite sides of the separation plate 24 respectively. In other words, the liquid inlet 22 is configured to be corresponding to the liquid inlet fin module 111, and the liquid outlet 23 is configured to be corresponding to the liquid outlet fin module 112. The position of the liquid inlet 22 is arranged to be corresponding to the highest heat point of the heat source to allow the coolant to cool and dissipate the heat from the highest heat point of the heat source at the lowest temperature, so as to achieve the best heat dissipation effect. In this specific embodiment, the protruding rib 25 is accommodated in the ditch 114 of the base 10 and abuts against each corresponding cooling fin 11, that is, the protruding rib 25 extends from the top plate 20 to abut against the liquid inlet fin module 111 of the base 10.

In the way of forming a ditch 114 in at least a part of the cooling fin 11, and designing the top plate 20 with a protruding rib 25 accommodated in the ditch 114 and abutting against each corresponding cooling fin 11, and using the separation plate 24 to divide each cooling fin 11 into a liquid inlet fin module 111 and a liquid outlet fin module 112 corresponding to the liquid inlet 22 and the liquid outlet 23 respectively, the coolant is blocked by the protruding rib 25 when passing through the liquid inlet fin module 111 and flowing to the bottom of each flow channel of the liquid inlet fin module 111, thereby adjusting the flow rate of the coolant and increasing the heat absorption of the coolant to improve the heat dissipation efficiency of the liquid cooling heat sink of the present disclosure. In some embodiments, the protruding rib 25 transversally blocks the top of each flow channel of the liquid inlet fin module 111 sideways, so the coolant is forced to flow towards the bottom of each flow channel to increase the flow rate, and the coolant absorbs more heat by flowing closer to the heat source, so as to effectively enhance the heat dissipation efficiency of the liquid cooling heat sink.

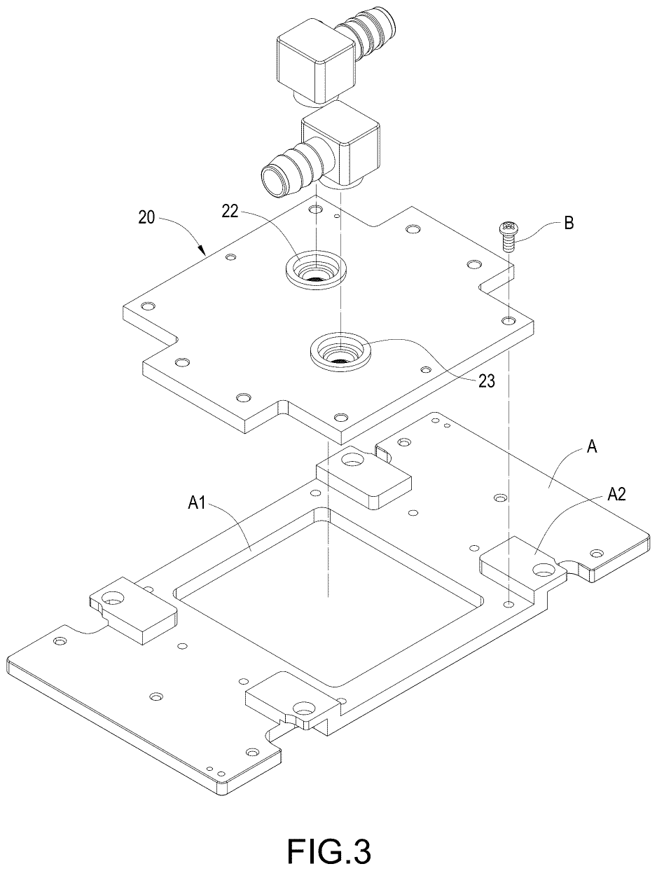

In FIG. 3, the liquid cooling heat sink of the present disclosure is fixed onto a mounting plate A. In some embodiments, the liquid cooling heat sink of the present disclosure is securely locked onto the mounting plate A by a plurality of bolts B, but the method of fixing the liquid cooling heat sink of the present disclosure is not limited thereto. The mounting plate A has a through slot A1 corresponding to the heat source and allowing the base plate 101 of the base 10 to pass through the through slot A1 to reach the heat source. In order to effectively position the liquid cooling heat sink and prevent each bolt B from causing the liquid cooling heat sink to deflect when it is locked, the mounting plate A is further provided with a plurality of positioning blocks A2 to limit the positioning of the liquid cooling heat sink through each positioning block A2, so as to facilitate the locking of each bolt B.

Referring to FIG. 4, the ratio of the depth of the ditch 114 to the height of the liquid inlet fin module 111 is greater than or equal to 0.1 and less than or equal to 1, which allows the coolant to be transversely blocked by the protruding rib 25 to force the coolant to flow towards the bottom of each flow channel. According to the experiments and tests conducted by the discloser of the present disclosure, the ratio of the depth of the ditch 114 to the height of the liquid inlet fin module 111 is about 0.5, that is, the depth of the ditch 114 is about a half of the height of each cooling fin 11 in the liquid inlet fin module 111, which gives the best turbulent effect of the coolant and achieves the best heat dissipation efficiency of the liquid cooling heat sink.

In this embodiment, the liquid inlet 22 and the liquid outlet 23 are respectively and diagonally arranged on two opposite sides of the separation plate 24, and the protruding rib 25 is located between the liquid inlet 22 and the liquid outlet 23, but the present disclosure is not limited thereto. In some embodiments as shown in FIGS. 1, 6 and 7, and the liquid inlet 22 is arranged at the top of the liquid inlet fin module 111 and near the rear side of the base 10, the liquid outlet 23 is arranged at the top of the liquid outlet fin module 112 and near the front side of the base 10, which maximizes the flow path of the coolant to increase the heat absorption and the heat dissipation efficiency, and substantially reduces the time difference between the diversion of the coolant from the liquid inlet 22 and the convergence of the coolant to the liquid outlet 23. However, the liquid inlet 22 and the liquid outlet 23 of some other embodiments are arranged on two opposite sides of the separation plate 24 in a mirror-symmetrical manner as needed. When the coolant enters into each flow channel of the liquid inlet fin module 111 from the liquid inlet 22 and splits in the forward or backward direction, the flow path of the coolant flowing towards the front is longer than the flow path of the coolant flowing towards the rear. Therefore, the flow rate of the coolant flowing in the front direction can be increased by arranging the protruding rib 25 between the liquid inlet 22 and the liquid outlet 23, thereby adjusting the time difference of the coolant entering into each flow channel of the liquid outlet fin module 112 in the forward or backward direction.

It is noteworthy that in the drawings and description shown in this embodiment, although both of the number of channels 114 and the number of protruding ribs 25 are only one, the present disclosure is not limited thereto, the number of channels 114 and the number of protruding ribs 25 may be adjustable according to the number of areas where the flow rate needs to be increased, these numbers are used for the convenience of understanding and for the illustration purpose, but those having ordinary skills in the art should be able to make different variations and derivations based on this disclosure, so more than two channels 114 and more than two protruding ribs 25 also fall within the scope of the present disclosure.

In FIGS. 1, 2, 6 and 7, the ratio of the volume of the liquid inlet fin module 111 to the volume of the liquid outlet fin module 112 is greater than or equal to 1 and less than or equal to 5. Through the adjustment of the flow rate of the coolant in the liquid inlet fin module 111 and the flow rate of the coolant in the liquid outlet fin module 112, the heat dissipation efficiency of the liquid cooling heat sink of the present disclosure is improved. Since the position of the liquid inlet 22 corresponds to the highest heat point of the heat source, therefore the ratio of the volume of the liquid inlet fin module 111 to the volume of the liquid outlet fin module 112 in this embodiment is set to about 2 based on the experiments and tests conducted by the discloser of the present disclosure. In other words, the volume of the liquid inlet fin module 111 is about twice the volume of the liquid outlet fin module 112, so that the flow of the coolant in the liquid inlet fin module 111 and the liquid outlet fin module 112 are optimally distributed, and the best cooling and heat dissipation effect is achieved.

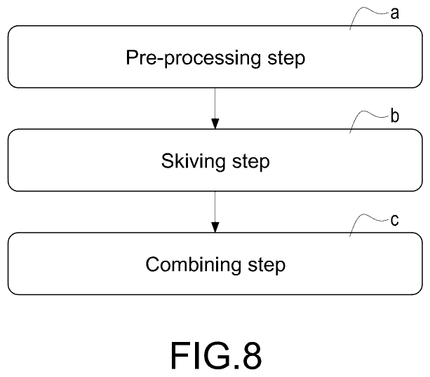

With reference to FIG. 8 for a manufacturing method of a liquid cooling heat sink of the present disclosure, the manufacturing method includes a Pre-processing step, a skiving step and a combining step.

In the pre-processing step, a base plate 101 is provided, and at least one trench (not shown in the figures) is formed on the upper surface of the base plate 101. The trench is formed on the base plate 101 by milling, extrusion or casting, etc., but the present disclosure is not limited thereto. The position and length of the trench correspond to the liquid inlet fin module 111 as described below.

In the skiving step, the upper surface of the base plate 101 is skived, such that a liquid inlet fin module 111 and a liquid outlet fin module 112 arranged at interval are formed on the upper surface of the base plate 101, and the trench is transformed into a ditch 114 when the base plate 101 is skived to form the liquid inlet fin module 111, wherein the ditch 114 is located on a side of the liquid inlet fin module 111 away from the upper surface of the base plate 101.

In the combining step, a top plate 20 is provided, wherein the lower surface of the top plate 20 is provided with a surrounding wall 21, a separation plate 24 and a protruding rib 25, the separation plate 24 and the protruding rib 25 are located in the surrounding wall 21, the protruding rib 25 is configured to be perpendicular to the separation plate 24, the top plate 20 is combined to the base plate 101 such that the surrounding wall 21 surrounds the liquid inlet fin module 111 and the liquid outlet fin module 112 and abuts against the base plate 101, and allows the separation plate 24 to block between the liquid inlet fin module 111 and the liquid outlet fin module 112, and the protruding rib 25 is accommodated in the ditch 114 and abuts against the liquid inlet fin module 111.

The top plate 20 further includes a liquid inlet 22 and a liquid outlet 23 arranged on two opposite sides of the separation plate 24 respectively, such that the liquid inlet 22 is arranged corresponding to the liquid inlet fin module 111, and the liquid outlet 23 is arranged corresponding to the liquid outlet fin module 112. The liquid inlet 22 is provided for entering a coolant into the liquid inlet fin module 111, splitting the flow of the coolant in the front-rear direction, and converging the coolant to flow into the liquid outlet fin module 112 in the front-rear direction before exiting from the liquid outlet 23.

By the combination the top plate 20 with the base plate 101, the protruding rib 25 is accommodated in the ditch 114 and abuts against the liquid inlet fin module 111, so that the coolant is blocked by the protruding rib 25 when passing through the liquid inlet fin module 111 and flow to the bottom, thereby adjusting the flow rate of the coolant, increasing the amount of heat absorbed by the coolant, and improving the heat dissipation efficiency of the liquid cooling heat sink. In addition, a trench is first formed on the upper surface of the base plate 101 by the pre-processing step, and then a high-density liquid inlet fin module 111 and a liquid outlet fin module 112 are integrally formed on the upper surface a of the base plate 101 by the skiving step, so that the trench is transformed into a ditch 114 which is located on the side of the liquid inlet fin module 111 away from the upper surface a of the base plate 101, thereby forming the ditch 114 on the high-density skived fin without destroying the skived fin structure, and achieving the effects of simple processing and low cost.

The liquid cooling heat sink of the present disclosure has a ditch 114 formed in at least a part of a cooling fin 11, a top plate 20 having a protruding rib 25 accommodated in the ditch 114 and abutting against each corresponding cooling fin 11, and a separation plate 24 is used to divide each cooling fin 11 into a liquid inlet fin module 111 and a liquid outlet fin module 112 corresponding to a liquid inlet 22 and a liquid outlet 23 respectively. Therefore, when the coolant passes through the liquid inlet fin module 111, it is blocked by the protruding rib 25 and flows to the bottom, thereby adjusting the flow rate of the coolant, increasing the heat absorption of the coolant, and improving the heat dissipation efficiency of the liquid cooling heat sink.

The present disclosure discloses a manufacturing method of a liquid cooling heat sink, wherein a trench is first formed on the upper surface of a base plate 101 through a pre-processing step, and then a high-density liquid inlet fin module 111 and a liquid outlet fin module 112 are integrally formed on the upper surface of the base plate 101 through a skiving step, so that the trench is transformed into a ditch 114 located on the side of the liquid inlet fin module 111 away from the upper surface of the base plate 101. Finally, a top plate 20 is combined with the base 10, so that a protruding rib 25 is accommodated in the ditch 114 and abuts against the liquid inlet fin module 111, and the coolant is blocked by the protruding rib 25 when passing through the liquid inlet fin module 111 and flowing to the bottom, thereby adjusting the flow rate of the coolant and increasing the coolant flow rate. The heat absorption at the bottom improves the heat dissipation efficiency of the liquid cooling heat sink.

In summation of the description above, the contents of the present disclosure are intended to enable those having ordinary skill in the art to clearly understand the technical characteristics of the present disclosure and to implement them accordingly, but not intended to limit the scope of patent protection of the present disclosure. In addition, the present disclosure may be implemented in many other ways not described herein, and without departing from the spirit and substance of the present disclosure, a person skilled in the art should be able to make a variety of corresponding changes and variations in accordance with the present disclosure, but these corresponding changes and variations should fall within the scope of the present disclosure.

What is claimed is:

1. A liquid cooling heat sink, comprising:
a base, comprising a plurality of cooling fins arranged in parallel, a notch is defined on at least a part of the cooling fins, and a ditch is jointly structured by a plurality of notches; and
a top plate, combined with the base and covering each the cooling fin, and comprising a liquid inlet, a liquid outlet, a separation plate and a protruding rib, the separation plate disposed parallel to each the cooling fin and dividing each of the cooling fins into a liquid inlet fin module and a liquid outlet fin module, the liquid inlet arranged corresponding to the liquid inlet fin module, the liquid outlet arranged corresponding to the liquid outlet fin module, the protruding rib accommodated in the ditch and abutting against the cooling fins correspondingly, and the protruding rib disposed perpendicular to each cooling fin and the separation plate.

2. The liquid cooling heat sink according to claim 1, wherein the notches are defined on the cooling fins of the liquid inlet fin module respectively.

3. The liquid cooling heat sink according to claim 2, wherein the protruding rib extends from the top plate to abut against the liquid inlet fin module.

4. The liquid cooling heat sink according to claim 2, wherein a ratio of a depth of the ditch and a height of the liquid inlet fin module is greater than or equal to 0.1 and less than or equal to 1.

5. The liquid cooling heat sink according to claim 4, wherein the ratio of the depth of the ditch and the height of the liquid inlet fin module is 0.5.

6. The liquid cooling heat sink according to claim 1, wherein the protruding rib is located between the liquid inlet and the liquid outlet.

7. The liquid cooling heat sink according to claim 1, wherein the liquid inlet and the liquid outlet are diagonally arranged on two sides of the separation plate opposite to each other.

8. The liquid cooling heat sink according to claim 1, wherein a ratio of a volume of the liquid inlet fin module to a volume of the liquid outlet fin module is greater than or equal to 1 and less than or equal to 5.

9. The liquid cooling heat sink according to claim 8, wherein the ratio of the volume of the liquid inlet fin module to the volume of the liquid outlet fin module is 2.

10. A manufacturing method of a liquid cooling heat sink, comprising:
a pre-processing step, providing a base plate, and forming a trench on the upper surface of the base plate;
a skiving step, skiving the upper surface of the base plate to form a liquid inlet fin module and a liquid outlet fin module, and transforming the trench into a ditch when skiving the base plate to form the liquid inlet fin module, wherein the ditch is located on a side of the liquid inlet fin module away from the upper surface of the base plate; and
a combining step, providing a top plate, wherein the lower surface of the top plate is provided with a surrounding wall, a separation plate and a protruding rib, the separation plate and the protruding rib are located in the surrounding wall, and the protruding rib is arranged perpendicular to the separation plate, combining the top plate with the base plate to make the surrounding wall surround the liquid inlet fin module and the liquid outlet fin module, the separation plate blocks between the liquid inlet fin module and the liquid outlet fin module, and the protruding rib is accommodated in the ditch and abuts against the liquid inlet fin module.
